(19) United States
(12) Patent Application Publication
(10) Pub. No.: US 2002/0074628 A1
(43) Pub. Date: Jun. 20, 2002

(54) Flexible wiring film, and semiconductor apparatus and system using the same

(76) Inventor: Katsuhisa Mochizuki, Kanagawa (JP)

Correspondence Address: FITZPATRICK CELLA HARPER & SCINTO, 30 ROCKEFELLER PLAZA, NEW YORK, NY, 10112, US

(21) Appl. No.: 10/005,697

(22) Filed: Dec. 7, 2001

(30) Foreign Application Priority Data
Dec. 14, 2000 (JP) 2000-380572

(51) Int. Cl. H01L 23/495

(52) U.S. Cl. 257/666

(57) ABSTRACT

In order to prevent forming bubbles on leads, in a solid-state image pickup apparatus provided with a solid-state image pickup element chip carrying solid-state image pickup elements electrically connected to leads on TAB tape, a protecting member for protecting the solid-state image pickup element chip, and a sealant for sealing them in the peripheral part of the solid-state image pickup element chip, each lead has an anchor hole formed in a portion in contact with the sealant.

### BACKGROUND OF THE INVENTION

1. Field of the Invention

The present invention relates to a flexible wiring film such as a TAB tape, flexible printed wiring board or the like, and a semiconductor apparatus and a system using the film and, more particularly, to a flexible wiring film used in image input devices such as video cameras, digital still cameras, and so on, and a semiconductor apparatus and a system using the film.

2. Related Background Art

Conventionally, CCD image pickup elements or MOS image pickup elements, which are used in the image input devices such as the video cameras, digital still cameras, and the like, are often formed on a semiconductor substrate such as a silicon wafer or the like. On the silicon wafer after completion of semiconductor steps, color filters and microlenses are made of an acrylic material or the like in the order named, in color filters and microlens forming steps.

Then a solid-state image pickup element chip cut into desired dimensions in a post-step is housed in a ceramic package or the like, the chip is electrically connected to leads by wire bonding, and a cap of a glass substrate is bonded onto the package.

FIG. 7 is a schematic, cross-sectional view of a solid-state image pickup apparatus. As shown in FIG. 7, a solid-state image pickup element chip 2 is provided with a plurality of solid-state image pickup elements such as CCD image pickup elements or MOS image pickup elements placed with their photoreceptive regions facing up in the figure, and microlenses 12 for focusing light on the image pickup elements, and leads 3, which are, for example, of copper foil sandwiched between insulating base films 8, 9 such as polyimide films, glass epoxy tapes, or the like, are electrically connected through Au bumps 4 on the solid-state image pickup element chip 2.

Further, a cover glass 1 is placed in parallel with and at a predetermined distance from the chip on the photoreceptive region side of the solid-state image pickup elements and is coated with one type or two types of thin films with a different index of refraction, called AR coat (Anti-Reflection Coating) 7a, and one surface of the cover glass 1 is bonded through a shield thin film 7b to the solid-state image pickup element chip 2 with the leads 3 connected thereto, with a sealant 5 such as an epoxy sealant or the like, filled with a filler in a high density. The solid-state image pickup apparatus using such leads 3 can be made more compact and thinner, for example, than ceramic packages produced by wire bonding.

Incidentally, since the bonding power is weak between the sealant 5 and Au plating laid on the surfaces of leads 3, delamination occurs readily between these. When such interfacial delamination occurs, moisture supplied under operating circumstances of semiconductor apparatus becomes easier to penetrate the surfaces of the semiconductor device chip mounted therein and corrode wires and electrodes on the devices, so as to cause electrical shorts or opens readily. It is thus necessary to prevent the bonding power from becoming weakened between the sealant 5 and the leads 3.

### SUMMARY OF THE INVENTION

It is, therefore, an object of the present invention to provide a flexible wiring film that is prevented from producing bubbles on the leads, and a semiconductor apparatus and a system using the flexible wiring film. It is another object of the present invention to provide a flexible wiring film that is enhances adhesion, and a semiconductor apparatus and a system using the flexible using film.

An aspect of the present invention is a flexible wiring film comprising a lead of an electric conductor, and an insulating film, wherein the lead has a hole in a portion exposed from the insulating film.

Another aspect of the present invention is an apparatus comprising a lead of a flexible wiring film, a device chip electrically connected to the lead, and a sealant for sealing a connection portion between the lead and the device chip, wherein the lead has a hole formed in a portion in contact with the sealant.

Still another aspect of the present invention is a semiconductor apparatus comprising a lead of a flexible wiring film, a semiconductor device chip electrically connected to the lead, and a protecting member for protecting a surface of the semiconductor device chip, which are sealed with a sealant in a peripheral portion of the semiconductor device chip, wherein the lead has a hole formed in a portion in contact with the sealant.

Still another aspect of the present invention is an image pickup system comprising a solid-state image pickup apparatus consisting of the aforementioned semiconductor apparatus; an optical system for focusing light on the solid-state image pickup apparatus; and a signal processing circuit for processing an output signal from the solid-state image pickup apparatus.

### BRIEF DESCRIPTION OF THE DRAWINGS

FIG. 1 is a schematic, perspective view of a solid-state image pickup apparatus as Embodiment 1 of the present invention;

FIG. 2 is a schematic, cross-sectional view of FIG. 1;

FIG. 3 is an enlarged view of a peripheral portion of a solid-state image pickup element chip of FIG. 2;

FIG. 4 is a plane view of a lead of FIG. 1;

FIG. 5 is an enlarged view of a peripheral portion of a solid-state image pickup element chip in a solid-state image pickup apparatus as Embodiment 2 of the present invention;

FIG. 6 is a block diagram of a solid-state image pickup system as Embodiment 3 of the present invention;

FIG. 7 is a schematic, cross-sectional view of a solid-state image pickup apparatus;

FIG. 8 is a plane view of a lead of FIG. 7;

FIG. 9 is a schematic, perspective view of an apparatus as embodiment 4; and

FIG. 10 is a cross-sectional view of a peripheral portion of an apparatus of FIG. 9.

### DETAILED DESCRIPTION OF THE PREFERRED EMBODIMENTS

According to embodiments of the present invention, a flexible wiring film has a plurality of leads made of an electric conductor such as copper or the like, and an insulating film of polyimide or the like for supporting these leads and for electrically insulating them.

A hole is formed in each of the leads exposed from the insulating film.

The flexible wiring film of this type is often used while it is bonded to a semiconductor element chip or the like of IC, LSI, and so on by Tape Automated Bonding. It is called a flexible printed wiring board, a TAB film or a TAB tape.

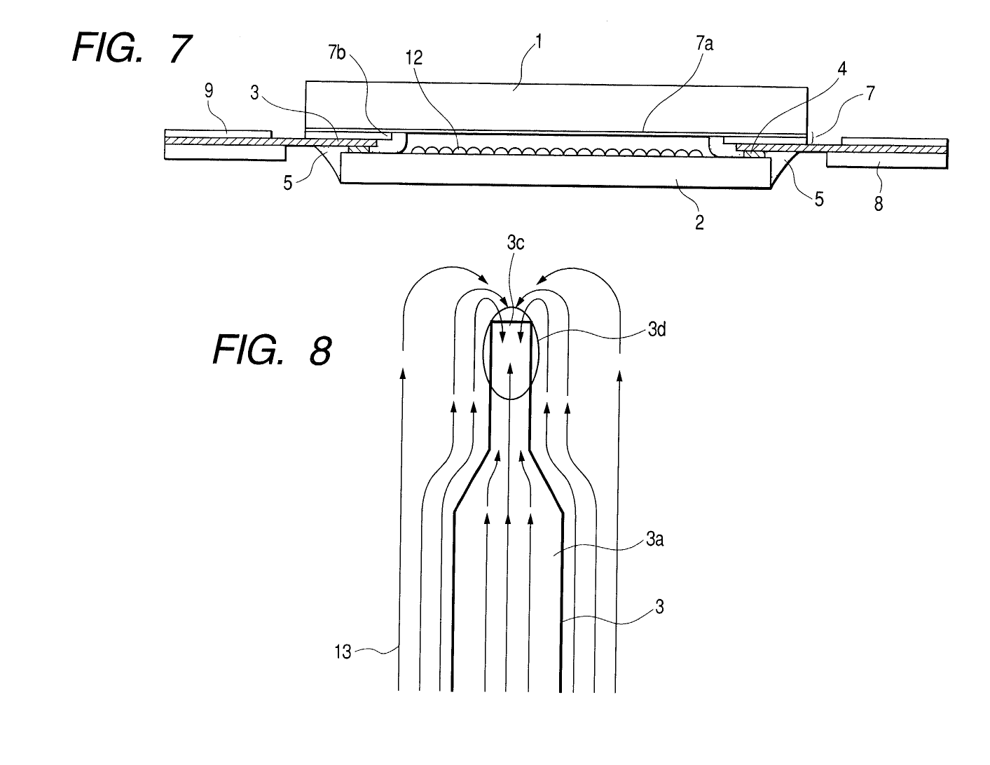

FIG. 8 is a plan view of a lead portion of TAB tape 11 as shown in FIG. 7. FIG. 8 shows magnitudes of flow rates of the sealant delivered, by arrows 13. The inventor found that the sealant flowing on the lead 3 flowed at lower rates than the sealant 5 flowing in the regions other than the region on the lead 3, as shown in FIG. 8. This is due to the difference between the flow resistance on the lead 3 and the flow resistance in the regions other than the lead 3.

Then the sealant 5 flowing in the regions other than the region on the lead 3 turns about at the tip 3c of the lead 3 because of the difference of flow rates of the sealant 5 and the like, and collides and merges with the sealant 5 having flowed on the lead 3 from the inner lead side. On that occasion, air is taken into the sealant in the merging region to make bubbles on the lead 3, i.e., in an oval region 3d of FIG. 8.

If there appear bubbles on the lead 3, the bonding power will become weakened between a coating layer 7 and the lead 3, so as to cause delamination between them, make a leak path between the inside and the outside of the package, and result in dew condensation due to moisture transmission in the package in certain cases. The inventor found that it was the cause of failure in securing electrical conduction or the like of the solid-state image pickup apparatus, so as to cause open defects.

In contrast to it, use of the flexible wiring film with the leads having their respective through holes (anchor holes) according to the present invention decreases the difference of flow rates between the sealant flowing to the inner lead tip on the leads and the sealant flowing to the inner lead tip from the paths other than the regions on the leads, whereby bubbles become hard to appear on the leads. In the present invention, it is not limited that there is a hole in a portion exposed from an insulating film. In a case that only one insulating film is in a side of leads the holes of leads may enhance adhesion with an object.

(Embodiment 1)

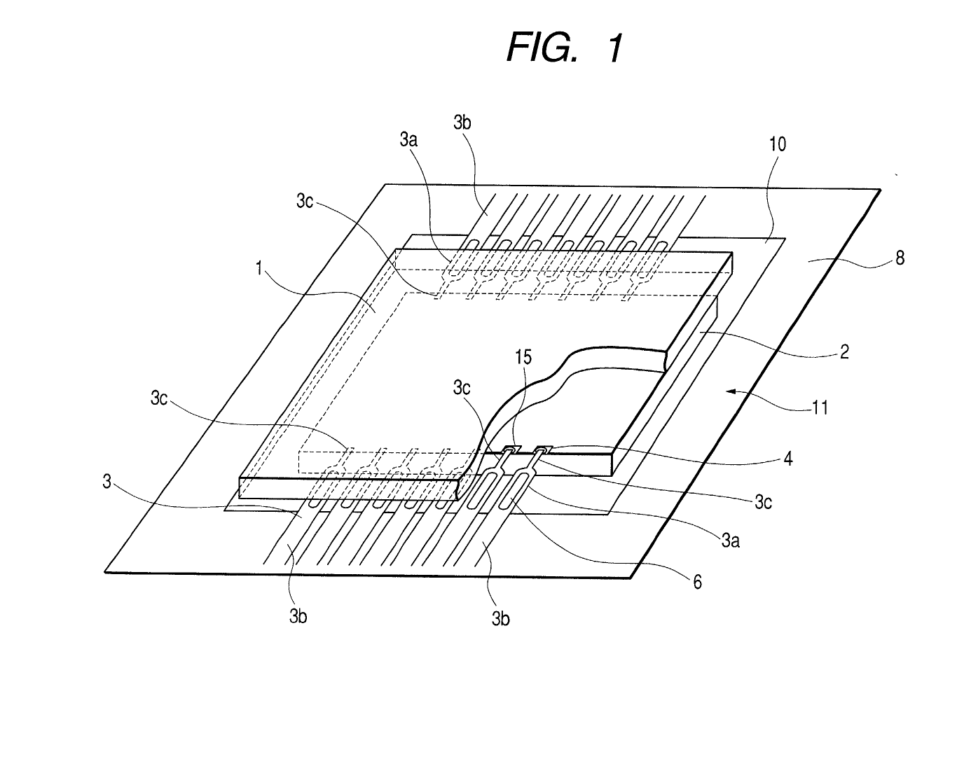

A semiconductor apparatus as Embodiment 1 of the present invention will be described below using an example of solid-state image pickup apparatus. FIG. 1 is a schematic, perspective view of the solid-state image pickup apparatus as such semiconductor apparatus. In the solid-state image pickup apparatus of the present embodiment, as shown in FIG. 1, a TAB tape 11 being a flexible wiring film is connected through Au bumps 4 on pad electrodes 15 of a solid-state image pickup element chip 2 in which a plurality of solid-state image pickup elements such as the CCD image pickup elements or the MOS image pickup elements are mounted.

The TAB tape 11 is a lamination of an insulating base film 8, such as a polyimide film, a glass epoxy tape, or the like, and leads 3 of copper foil or the like provided with their respective anchor holes 6. Each of the leads 3 is connected at a tip 3c of inner lead 3a part to an Au bump 4 and is laminated at outer lead 3b part with the insulating base film 8.

The solid-state image pickup element chip 2 is disposed in device hole 10 without the insulating base film 8 while being kept in a state in which it is coupled to a cover glass 1 being a protecting member provided with one type or two types of thin films with a different refractive index, called an AR coat (Anti-Reflection Coating).

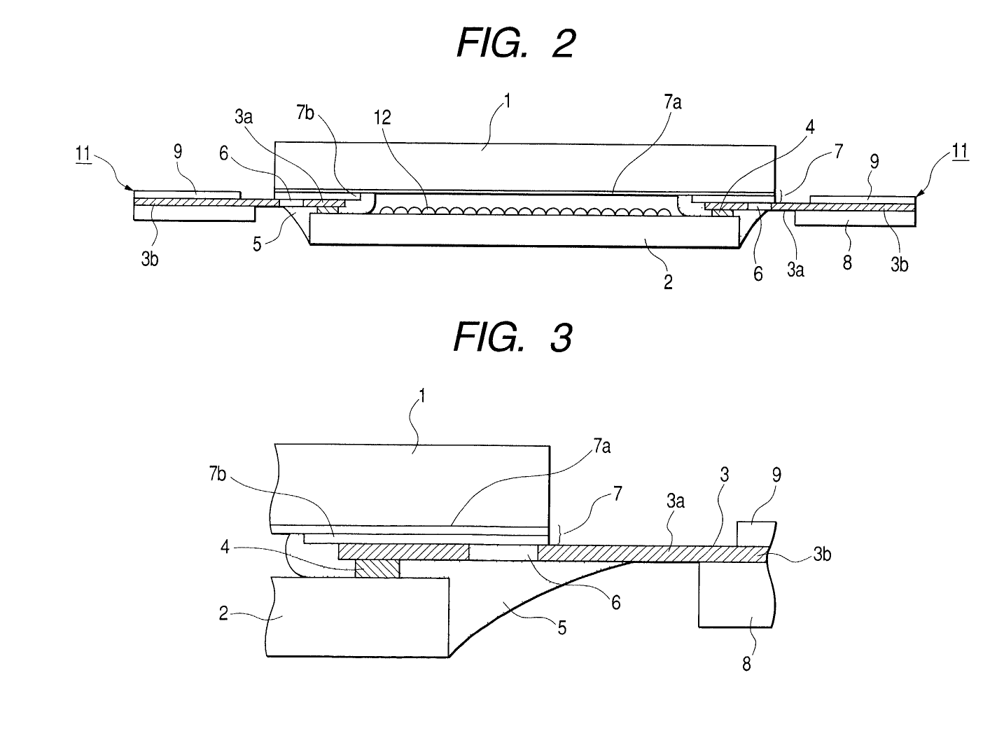

FIG. 2 is a schematic, cross-sectional view of FIG. 1. The solid-state image pickup apparatus of the present embodiment is provided with microlenses 12 on the photoreceptive surface of the solid-state image pickup element chip 2 and the AR coat 7a is provided as described above. The cover glass 1 is equipped with a shield thin film 7b. The cover glass 1 side and the solid-state image pickup element chip 2 side are bonded to each other with the sealant 5, such as an epoxy based sealant or the like, filled with a filler in a high density, and a coating layer 7 is formed between the leads 3 and the cover glass 1. Numeral 9 is an insulating film which is optionally disposed on leads 3 in an opposite side of the insulating base film 8. In FIG. 2, portions similar to those in FIG. 1 are denoted by the same reference symbols.

FIG. 3 is an enlarged view of the peripheral portion of the solid-state image pickup element chip 2 of FIG. 2. As shown in FIG. 3, the anchor holes 6 are formed so as to be wholly placed under the cover glass 1 in the peripheral portion of the solid-state image pickup element chip 2.

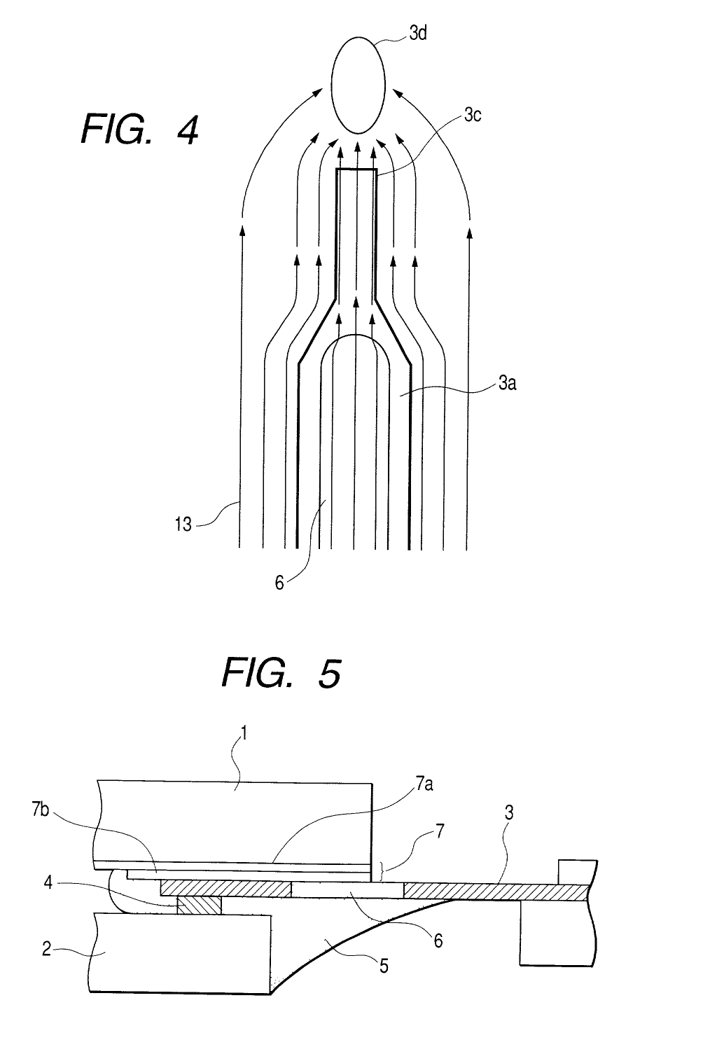

FIG. 4 is a plane view of a lead 3 of FIG. 1. The description will be given by dividing the lead 3 into the tip portion 3c of the inner lead 3a and the portion on the outer lead side of the inner lead 3a for convenience' sake, as shown in FIG. 4. Since the anchor hole 6 is formed in the wide part of the inner lead 3a, the difference is not too large between flow rates of the sealant 5 flowing on the wide part and the sealant 5 flowing in the regions other than the region on the lead 3.

At the tip portion 3c of the inner lead 3a, since there is no anchor hole 6 formed there, the sealant 5 flowing in this region comes to make a difference of flow rate from the sealant 5 flowing in the regions other than the region on the lead 3. However, since the flow rates of the sealant 5 are approximately equal, regardless of whether or not on the lead 3, up to the wide part of the inner lead 3a as described above, the position of collision between the sealant 5 flowing on the lead 3 and the sealant 5 flowing in the regions other than the region on the lead 3 is located ahead of the lead 3, i.e., in an oval region 3d of FIG. 4, so that there appear no bubbles on the lead 3.

Production steps of the solid-state image pickup apparatus of the present embodiment will be described below. First, the TAB tape 11 is produced. The TAB tape 11 is formed by processing a resin tape, e.g., a polyimide base tape 8, for example, 50 μm to 125 μm thick and 48 mm wide, by punching with a die or the like to form the device hole 10 being an aperture for mounting of the semiconductor chip and unrepresented perforations being positioning holes for carriage of tape carrier.

In the mounting of solid-state image pickup elements using the TAB tape 11, the distance between the solid-state image pickup element chip 2 and the device hole 10 is set as wide as about 1.5 to 2.0 mm in consideration of application of the sealant 5. Further, in order to maintain high strength of the inner leads 3a of the TAB tape 11 bonded to the Au bumps 4 formed on the solid-state image pickup element chip 2, the portion where the device hole 10 is formed between the outer lead 3b and the tip 3c is made wider than the size at the tip 3c.

Next, the insulating base film 8 is laminated with rolled copper foil or electroplated copper foil about 18 to 35 μm thick by bonding with an adhesive. Then a photoresist is applied onto the copper foil in order to form patterns and the leads 3, and is then subjected to exposure and development for formation of patterns of various wires, and the leads 3. After that, a backing resist is applied in order to protect the back surfaces of the inner leads 3a of copper foil exposed in the device hole 10 by punching, from etching. Thereafter, the copper foil is subjected to an etching step to form the patterns and leads 3.

The photoresist and backing resist, which become unnecessary after the etching, are dissolved and removed with an alkali solution, and then a solder resist is printed for protection and insulation of the copper wiring patterns except for those in the connection regions. The copper wiring patterns are plated with Sn, Au, or the like by electroplating in order to enhance bonding performance.

The anchor holes 6 are produced by a step similar to the step of the copper foil etching of the TAB tape 11. However, the minimum width of the anchor holes 6 is determined as 1.0×T (T: thickness of copper foil). Further, the anchor holes 6 are formed in the following dimensions: for example, where the width of the inner lead 3a wider than the size at the tip 3c is 35 μm, the longitudinal length of the hole is arbitrary and the transverse (widthwise) length of the hole is, for example, 25 μm.

The transverse length of the anchor holes 6 can be determined according to the strength of the lead body, the width of the inner lead 3a, and the flow resistance of the lead body, and the shape of the anchor holes 6 does not have to be limited to the shape of the elongated hole as shown in FIG. 4, but may be, for example, a circular shape having the diameter of 25 μm, or at least two or more circles arranged.

Subsequently, the Au bumps 4 are formed on the pad electrodes 15 on the solid-state image pickup element chip 2, the Au bump 4 side is preliminarily heated to about 150° C., and in that state the tip 3c of each inner lead of the TAB tape is joined thereto through use of a bonding tool by a single point bonding method. The tip 3c of each inner lead of the TAB tape 11 may also be bonded to the bump by thermosonic pressure bonding or the like.

After that, the cover glass 1 for preventing attachment of dust to the microlenses 12 and others is placed a predetermined distance apart from and in parallel with the solid-state image pickup elements. Then the sealant 5, e.g., a thermosetting resin or an ultraviolet-curing resin is delivered onto the peripheral region of the solid-state image pickup element chip 2 from a dispenser or the like, the cover glass 1 side and the solid-state image pickup element chip 2 side are attached to each other, and the sealant 5 is hardened by applying heat or by radiating ultraviolet light.

When the sealant 5 is an ultraviolet-curing resin, the shield thin film 7b serves as a mask against ultraviolet light and the sealant is cured under irradiation with ultraviolet light whereby the resin can be prevented from flowing into the effective image pickup area inside the shield thin film 7b. Therefore, the ultraviolet-curing resin is used as the sealant 5 in the present embodiment.

(Embodiment 2)

A semiconductor apparatus as Embodiment 2 of the present invention will be described below using an example of solid-state image pickup apparatus. FIG. 5 is a perspective view of the solid-state image pickup apparatus and is equivalent to FIG. 3. When FIG. 5 is compared with FIG. 3, the longitudinal length of the anchor holes 6 is different and longer in the present embodiment. Namely, the anchor hole 6 shown in FIG. 3 is formed in the size wholly placed under the cover glass 1, whereas the anchor hole 6 shown in FIG. 5 extends in part from under the cover glass 1 to the outside.

When the anchor hole 6 is formed in the form as shown in FIG. 5, a force exerted on the connection portion between the lead 3 and the Au bump 4 can be weaker than in the case wherein the anchor hole 6 is formed in the form shown in FIG. 3. Namely, the stress is also distributed to the anchor hole 6 side, thereby relatively decreasing the stress applied to the Au bump 4.

In the configuration wherein the anchor hole 6 is wholly placed below the cover glass 1, since there is the difference of flow resistances before arrival of the sealant 5 at the anchor hole 6 formed in the inner lead 3a, flow rates are different at the time of application of the sealant, and then the sealant 5 flows at an equal flow rate after arrival at the anchor hole 6. Namely, there arises a time lag though it depends upon the distance of the hole.

In contrast to it, since the flow resistances are equal between inside the hole and outside the lead 3 in the case of the longer anchor hole 6 extended from under the cover glass 1, a time lag hardly occurs and uniformity of flowing-in can be enhanced in this part.

(Embodiment 3)

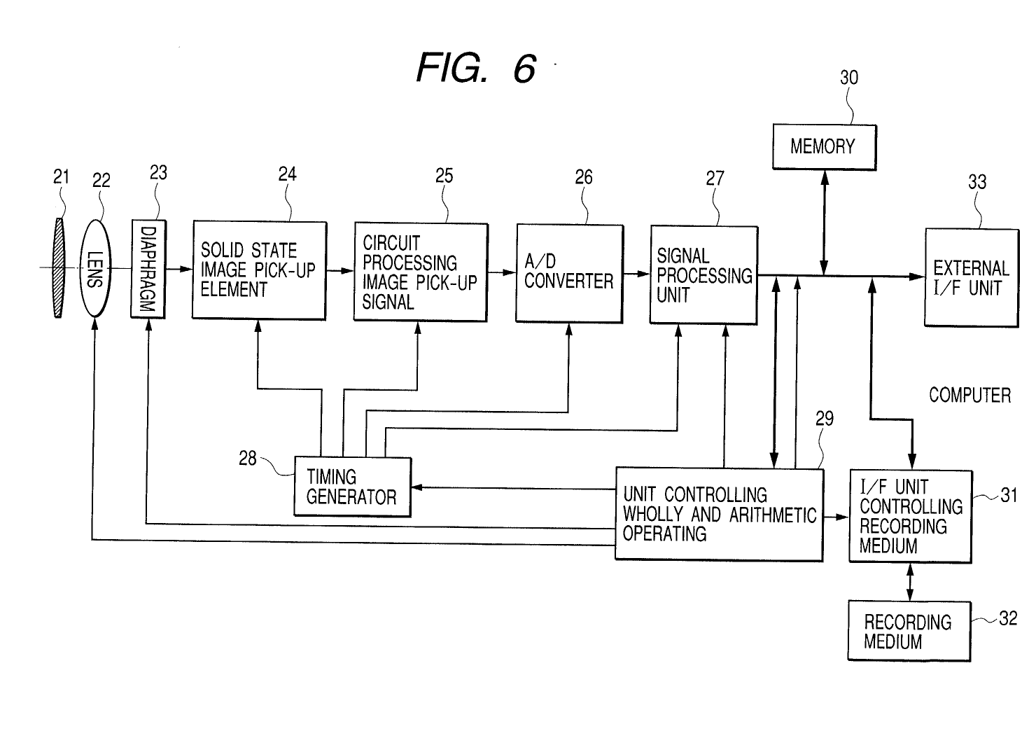

FIG. 6 is a block diagram of an image pickup system according to Embodiment 3 of the present invention. In FIG. 6, reference numeral 21 designates a barrier serving as a protector for a lens and as a main switch; numeral 22 a lens for focusing an optical image of an object on a solid-state image pickup element 24; 23 a diaphragm for variably controlling the quantity of light passing through the lens; 24 a solid-state image pickup element, as described in Embodiments 1 and 2, for capturing the object image focused by the lens 22, as an image signal; 25 an image pickup signal processing circuit for effecting processing including various corrections, clamping, etc. on the image signal outputted from the solid-state image pickup element 24; 26 an A/D converter for performing analog-digital conversion of the image signal outputted from the solid-state image pickup element 24; 27 a signal processing unit for effecting various corrections on the image data outputted from the A/D converter 26 and compressing data; 28 a timing generator for outputting various timing signals to the solid-state image pickup element 24, to the image pickup signal processing circuit 25, to the A/D converter 26, and to the signal processing unit 27; 29 a whole control-arithmetic unit for wholly controlling various arithmetic operations and the entire still video camera; 30 a memory for temporarily saving image data; 31 a recording medium control interface unit for recording or reading data in or out of a recording medium; 32 a recording medium that can be attached or detached, such as a semiconductor memory or the like, for recording or reading of image data; 33 an external interface (I/F) unit for communication with an external computer or the like.

In the next place, the operation of FIG. 6 will be described. When the barrier 21 is opened, the main power is turned on. Then the power of the control system is turned on, and the power of the image pickup system circuit including the A/D converter 26 and others is further turned on. Then, in order to control an exposure amount, the whole control-arithmetic unit 29 brings the diaphragm 23 to the full aperture and a signal outputted at this time from the solid-state image pickup element 24 is guided through the image pickup signal processing circuit 25 to the A/D converter 26. The A/D converter 26 performs the A/D conversion of the signal and outputs the result to the signal processing unit 27. The signal processing unit 27 makes the whole control-arithmetic unit 29 calculate an exposure based on the data.

Brightness is judged based on the result of this photometry and the whole control-arithmetic unit 29 controls the diaphragm in accordance with the result of the judgment. Next, the whole control-arithmetic unit 29 calculates the distance to the object by extracting a high-frequency component, based on the signal outputted from the solid-state image pickup element 24. After that, the lens 22 is driven and whether focus is achieved is determined. When it is determined that the lens is out of focus, the lens 22 is again driven and distance measurement is carried out.

After an in-focus state is confirmed, regular exposure is started. After completion of the exposure, an image signal outputted from the solid-state image pickup element 24 is subjected to corrections and others in the image pickup signal processing circuit 25, and the resultant signal is further subjected to the A/D conversion in the A/D converter 26. A digital signal obtained is processed in the signal processing unit 27 and the whole control-arithmetic unit 29 stores the resultant in the memory 30. After that, the data stored in the memory 30 is recorded through the recording medium control I/F unit 31 into the detachable recording medium 32 such as a semiconductor memory or the like under control of the whole control-arithmetic unit 29. The data may also be guided through the external I/F unit 33 directly into a computer or the like to be subjected to processing of image.

It is also preferable to integrate the circuits of reference numerals 25 to 28, together with the solid-state image pickup element 24, on one chip by the CMOS process.

(Embodiment 4)

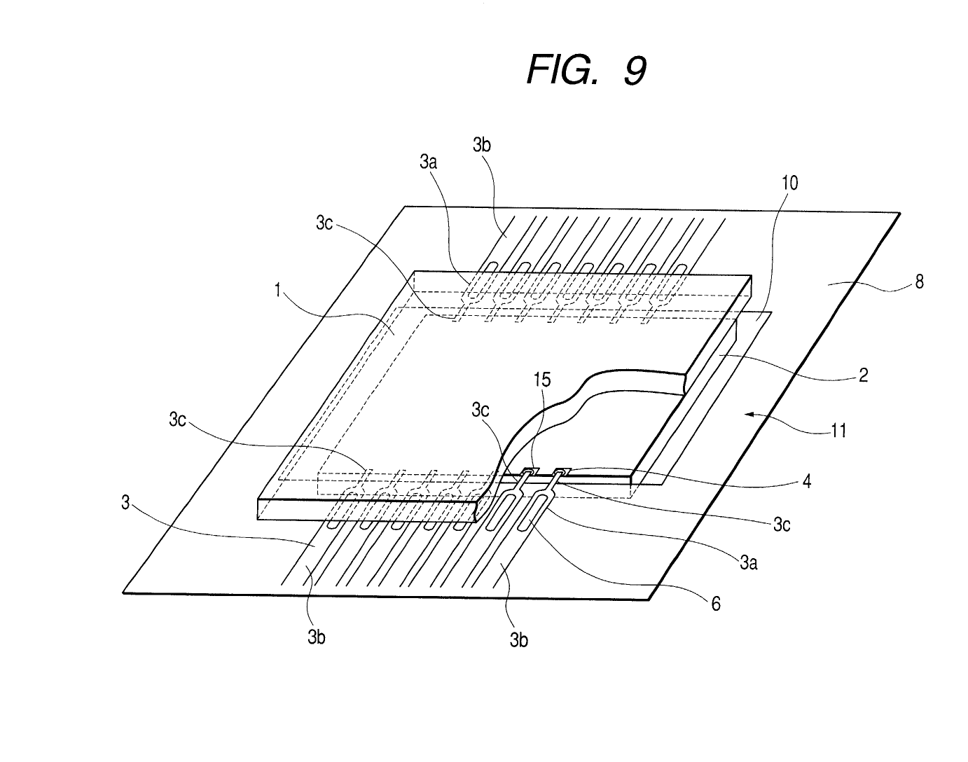

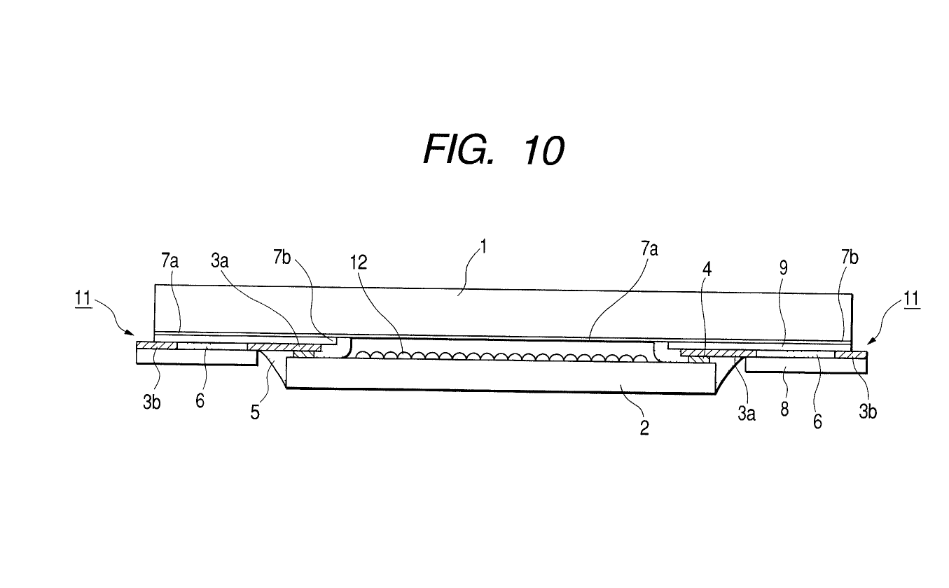

FIGS. 9 and 10 show an embodiment 4 of the present invention. There is no insulating film corresponding to the insulating film 9 of FIG. 1 in an apparatus of the embodiment 4.

In FIGS. 9 and 10, portions similar to those in FIGS. 1 and 3 are denoted by the same reference symbols.

Each of the embodiments of the present invention was described above as an example where the TAB tape 11 was used in the solid-state image pickup apparatus and system, but the TAB tape 11 can also be used in the apparatus other than the solid-state image pickup apparatus; e.g., ICs, LSIs, DMDs, display devices, and so on.

What is claimed is:

1. A flexible wiring film comprising a lead of an electric conductor, and an insulating film, wherein said lead has a hole in a portion exposed from said insulating film.

2. The flexible wiring film according to claim 1, wherein said hole is formed in a portion wider than a tip of said lead.

3. The flexible wiring film according to claim 1 or 2, wherein said hole is of a shape selected from a circle, an elongated circle, an oval, and an elongated oval.

4. An apparatus comprising a lead of a flexible wiring film, a device chip electrically connected to the lead, and a sealant for sealing a connection portion between said lead and said device chip, wherein said lead has a hole formed in a portion in contact with said sealant.

5. A semiconductor apparatus comprising a lead of a flexible wiring film, a semiconductor device chip electrically connected to the lead, and a protecting member for protecting a surface of the semiconductor device chip, which are sealed with a sealant in a peripheral portion of said semiconductor device chip, wherein said lead has a hole formed in a portion in contact with the sealant.

6. The semiconductor apparatus according to claim 5, wherein at least a part of said hole is formed in a region where a portion of the lead is sandwiched between said semiconductor device chip and said protecting member.

7. The apparatus according to claim 4, wherein said hole is formed in a portion wider than a tip of said lead.

8. The semiconductor apparatus according to claim 5, wherein at least one of a layer for preventing reflection of external light and a layer for preventing multiple reflection is formed between said lead and said protecting member.

9. An image pickup system comprising:
a solid-state image pickup apparatus consisting of the semiconductor apparatus as set forth in either one of claims 5 to 8;
an optical system for focusing light on said solid-state image pickup apparatus; and
a signal processing circuit for processing an output signal from said solid-state image pickup apparatus.

10. A flexible wiring film comprising a lead of an electric conductor, and an insulating film, wherein said lead has a hole adapted to be adhered to an object.

11. A flexible wiring film comprising a lead of an electric conductor, and an insulating film, wherein said lead has a hole for enhancing to adhere.
